(19) United States
(12) Patent Application Publication
(10) Pub. No.: US 2006/0019499 A1
(43) Pub. Date: Jan. 26, 2006

(54) Method of forming passivation layer in semiconductor device

(75) Inventor: Young Geun Jang, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-Do (KR)

(21) Appl. No.: 11/119,646

(22) Filed: May 2, 2005

(30) Foreign Application Priority Data
Jul. 22, 2004 (KR) 2004-57185

(51) Int. Cl. H01L 21/469

(52) U.S. Cl. 438/763; 438/788; 438/792

(57) ABSTRACT

Provided is a method of forming a passivation layer of a semiconductor device, using a high density plasma-enhanced chemical vapor deposition (HDPCVD) in order to form an excellent film without a void between metal lines which are being narrower. During the process of HDPCVD that utilizes SiH₄ and O₂ gas as an reaction gas, a first insulation film is formed along the surface of an overall structure including metal lines in a low biasing power and a second insulation film is formed on the first insulation film in a high biasing power enough to bury the spaces between the metal lines. Thus, it is possible to fill up (i.e., gap-filling) the spaces between the metal lines with the second insulation film without a void, and to prevent a junction leakage current due to an inflow of charges into the metal lines due to the plasma because the first insulation film protects the metal lines from damages by the gaseous plasma generated while forming the second insulation film.

### BACKGROUND

1. Field of the Invention

The present invention relates to a method of forming a passivation layer of a semiconductor device and specifically, to a method of forming a passivation layer of a semiconductor device, capable of preventing a junction leakage current generated due to an inflow of charges into metal lines by plasma when a high density plasma-enhanced chemical vapor deposition (HDPCVD) is applied thereto in order to form an excellent film without a void between metal lines which are being narrower.

2. Discussion of Related Art

In general, a passivation layer, which is usually employed in a nano-dimension flash device, a DRAM device, and other semiconductor device, is provided to sufficiently fill up spaces between metal lines by means of oxides and nitrides, which restrains generation of voids and thereby eliminates troubles in the subsequent processing step. Such a passivation layer should be required of the following functions on merit.

First, it should be capable of acting as a barrier for protecting the underlying circuit chemically and mechanically.

Second, it must have the characteristics of moisture barrier, stress controllability, good hermeticity, minimal capacitance, and good gap-filling capacity.

However, with higher integration density of semiconductor devices, spaces between metal lines is becoming narrower to raise an aspect ratio thereof and thereby it is being difficult for the metal lines to be form of a complete gap-filling structure without a void. As a result, residues generated through the subsequent processing step crowds in voids, causing processing defects to induce fails of the device. In other words, the residues may be explosive out of the voids when heat is applied thereto.

In order to restrain the generation of void by sufficiently gap-filling the spaces between the metal lines, a passivation layer is formed with an oxide and nitride stacked therein by sequentially depositing the oxide by means of HDPCVD using Ar, SiH₄, and O₂ gas and the nitride by means of plasma-enhanced CVD in order. When the oxide is deposited by means of the HDPCVD, Ar gas is utilized as the plasma gas under high biasing power in order to progress the process in the condition of completing the gap-filling structure between the metal lines. However, during the procedure of forming such an oxide, the plasma of the Ar gas causes charges to flow into the metal lines, influencing its underlying gate. The inflow charges form a conductive channel for leakage current between a gate and a source junction. Such a leakage current degrades the electrical characteristics and reliability of the device, as well as disturbing operations of calibrating current values in various test modes.

### SUMMARY OF THE INVENTION

The present invention is directed to a method of forming a passivation layer of a semiconductor device, capable of preventing a junction leakage current due to plasma while forming a good film without a void between metal lines.

An aspect the present invention is to provide a method of forming a passivation layer of a semiconductor device, comprising the steps of: loading a substrate, in which pluralities of metal lines are formed, into a high density plasma chemical vapor deposition equipment; forming a first insulation film on the overall structure including the metal lines, under a first processing condition, preventing damages due to plasma; forming a second insulation film on the first insulation film under a second processing condition, gap-filling spaces between the metal lines; and forming a third insulation film on the second insulation film after unloading the substrate out of the high density plasma chemical vapor deposition equipment.

Preferably, the first insulation film is deposited in the thickness of 500 through 1000 Å.

Preferably, the first processing condition is established with SiH₄ reaction gas of 30 through 40 sccm and O₂ reaction gas 60 through 80 sccm, under source power of 3000 through 4000 W, and in biasing power lower than 300 W. Or, the first processing condition is established with SiH₄ reaction gas of 30 through 40 sccm, O₂ reaction gas 60 through 80 sccm, and Ar reaction gas of 100 through 120 sccm, under source power of 3000 through 4000 W, and in biasing power lower than 300 W.

Preferably, the second insulation film is formed of an oxide deposited in 1.5 through 2.0 times thicker than the metal line.

Preferably, the second insulation film is formed by way of plasma chemical vapor deposition using SiH₄ and O₂ gas as a reaction gas.

Preferably, the second processing condition is established with SiH₄ reaction gas of 50 through 60 sccm and O₂ reaction gas that is supplied to be 1.6 through 2.0 times more than the SiH₄ gas, under source power of 3000 through 4000 W, and in biasing power of 2500˜3500 W.

Preferably, the third insulation film is formed of a nitride deposited by way of plasma enhanced chemical vapor deposition.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention. In the drawings:

FIGS. 1A through 1C are sectional diagrams illustrating processing steps by the method of forming a passivation layer of a semiconductor device in accordance with the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numerals refer to like elements throughout the specification. It will also be understood that when a layer is referred to as being “on” another layer or substrate, it can be directly on the other layer or substrate, or intervening layers may also be present.

Hereinafter, it will be described about an exemplary embodiment of the present invention in conjunction with the accompanying drawings.

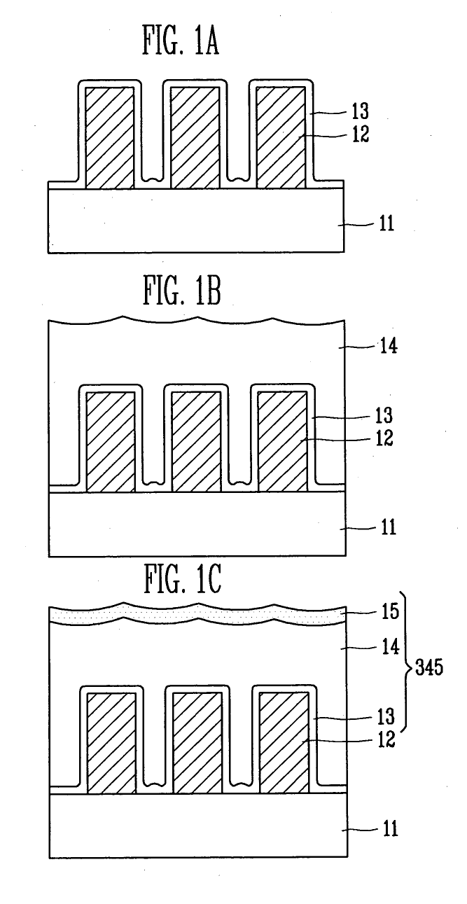

FIGS. 1A through 1C are sectional diagrams illustrating processing steps by the method of forming a passivation layer of a semiconductor device in accordance with the present invention.

Referring to FIG. 1A, after loading a substrate 11, in which pluralities of metal lines 12 are formed, on a deposition equipment of HDPCVD, a first insulation film 13 is formed on the overall structure including the metal lines 12 in a first processing condition of minimizing damages due to plasma.

In the former step, the first insulation film 13 is formed of an oxide deposited in 500˜1000 Å in thickness, minimizing an overhang effect together with protecting the metal lines 12 from damages due to plasma generated at the subsequent processing step. The first processing condition is established with SiH₄ reaction gas of 30˜40 sccm and O₂ reaction gas 60˜80 sccm, under source power of 3000˜4000 W for generating gaseous plasma, and in biasing power lower than 300 W for easily gap-filling spaces between metal lines 12 by inducing the reaction gas toward the substrate 11. The gap-filling ability may be degraded because the first insulation film 13 is formed under such a low biasing power, but there is no influence directing to the metal lines 12 due to damages by the O₂ plasma.

Meanwhile, for the first processing condition, Ar gas may be applied in addition to the SiH₄ and O₂ reaction gas, in the amount of 100˜120 sccm. In this situation, while the Ar plasma may affect directly to the metal lines 12, there is no considerable influence to the property of the metal lines because it uses the low biasing power.

Referring to FIG. 1B, a second insulation film 14 is formed on the first insulation film 13 under a second processing condition for obtaining a good gap-filling feature without a void between the metal lines 12.

In the processing step shown in FIG. 1B, the second insulation film 14 is formed of an oxide deposited in 1.5 through 2.0 times thicker than the height of the metal lines 12 in order enough to gap-fill the spaces between the metal lines 12. The second processing condition is established with SiH₄ reaction gas of 50˜60 sccm and O₂ reaction gas that is supplied to be 1.6 through 2.0 times more than the SiH₄ gas to regulate a reflective index RI of the second insulation film 14 within 1.460±1.02, under source power of 3000˜4000 W for generating gaseous plasma, and in biasing power of 2500˜3500 W for easily gap-filling spaces between metal lines 12 by inducing the reaction gas toward the substrate 11. Such a high biasing power is helpful to providing a good gap-filling capability to fill up the spaces between the metal lines 12 by the second insulation film 14, but the gaseous plasma generated while forming the second insulation film 14 may cause charges to flow into the metal lines 12. However, the first insulation film 13 acts as a barrier against the charge inflow toward the metal lines 14 due to the plasma, preventing the generation of junction leakage current that has been a problem by the use of Ar gas under the high biasing power as the conventional case. In other words, the second insulation film 14 is formed in the high biasing power with the reaction gas of SiH₄ and O₂.

Referring to FIG. 1C, after unloading the substrate 11, in which the first and second insulation films 13 and 14 are formed, out of the vapor deposition equipment of HDPCVD, a third insulation film 15 is deposited on the second insulation film 14. As a result, the first, second, and third insulation films, 13, 14, and 15, being stacked in sequence, complete the structure of a passivation layer 345.

During this, the third insulation film 15 is formed of a nitride deposited thereon by way of PECVD.

As stated above, the present invention is applicable to using a high density plasma-enhanced chemical vapor deposition (HDPCVD) in order to form an excellent film without a void between metal lines which are being narrower. During the process of HDPCVD, a first insulation film is formed the low biasing power for preventing the metal lines from being damaged by plasma and next a second insulation film is formed on the first insulation film in a high biasing power enough to fill up the spaces between the metal lines. Thus, it is possible to improve the electrical characteristic and reliability of the semiconductor device by preventing a junction leakage current due to an inflow of charges into the metal lines due to the plasma while filling (i.e., gap-filling) up the spaces between the metal lines with the second insulation film without a void. Moreover, since the first and second insulation films for gap-filling the spaces between the metal lines are formed in the same vapor deposition equipment, it is possible to assure the same processing condition. And, since Ar plasma is not used while forming the second insulation film for the gap-filling structure, the capability for gap-filling is improved as well as removing, damages due to the plasma.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A method of forming a passivation layer of a semiconductor device, the method comprising the steps of:
loading a substrate, in which pluralities of metal lines are formed, into a high density plasma chemical vapor deposition equipment;
forming a first insulation film on the overall structure including the metal lines, under a first processing condition, preventing damages due to plasma;
forming a second insulation film on the first insulation film under a second processing condition, gap-filling spaces between the metal lines; and
forming a third insulation film on the second insulation film after unloading the substrate out of the high density plasma chemical vapor deposition equipment.

2. The method as set forth in claim 1, wherein the first insulation film is deposited in the thickness of 500 through 1000 Å.

3. The method as set forth in claim 1, wherein the first processing condition is established with SiH₄ reaction gas of 30 through 40 sccm and O₂ reaction gas 60 through 80 sccm, under source power of 3000 through 4000 W, and in biasing power lower than 300 W.

4. The method as set forth in claim 1, wherein the first processing condition is established with SiH₄ reaction gas of 30 through 40 sccm, O₂ reaction gas 60 through 80 sccm, and Ar reaction gas of 100 through 120 sccm, under source power of 3000 through 4000 W, and in biasing power lower than 300 W.

5. The method as set forth in claim 1, wherein the second insulation film is formed of an oxide deposited in 1.5 through 2.0 times thicker than the metal line.

6. The method as set forth in claim 1, wherein the second insulation film is formed by way of plasma chemical vapor deposition using SiH₄ and O₂ gas as a reaction gas.

7. The method as set forth in claim 1, wherein the second processing condition is established with SiH₄ reaction gas of 50 through 60 sccm and O₂ reaction gas that is supplied to be 1.6 through 2.0 times more than the SiH₄ gas, under source power of 3000 through 4000 W, and in biasing power of 2500˜3500 W.

8. The method as set forth in claim 1, wherein the third insulation film is formed of a nitride deposited by way of plasma enhanced chemical vapor deposition.
